(19) United States
(12) Patent Application Publication
(10) Pub. No.: US 2015/0145540 A1
(43) Pub. Date: May 28, 2015

(54) SEMICONDUCTOR INSPECTION SYSTEM AND METHOD FOR PREVENTING CONDENATION AT INTERFACE PART

(71) Applicant: Tokyo Electron Limited, Tokyo (JP)

(72) Inventors: Shigekazu Komatsu, Yamanashi (JP); Takaaki Hoshino, Yamanashi (JP)

(21) Appl. No.: 14/412,650

(22) PCT Filed: Jun. 18, 2013
(86) PCT No.: PCT/JP2013/067161

§ 371 Date: Jan. 2, 2015

(30) Foreign Application Priority Data
Jul. 2, 2012 (JP) 2012-148263

(51) Int. Cl. G01R 31/26; G01R 1/073

(52) U.S. Cl. CPC G01R 31/2601; G01R 1/07342
USPC 324/750.03; 324/750.14

(57) ABSTRACT

Provided are a semiconductor inspection system and a method for preventing condensation at an interface part. The inspection system is characterized by being equipped with: a probe apparatus configured to bring a probe into contact with a target object whose temperature is controlled so that the probe is electrically connected with the target object; a tester configured to inspect the target object by supplying an inspection signal to the target object and detect an output signal outputted from the target object; an interface part which electrically connects the probe with the tester; a vacuum seal mechanism configured to seal the interface part in an airtight state; a gas exhaust unit configured to evacuate the interior of the interface part to a depressurized atmosphere; and a dry gas supply unit configured to supply a dry gas into the evacuated interface part while controlling a flow rate of the dry gas.

### CROSS REFERENCE

This application is a national stage application of PCT application No. PCT/JP2013/067161 filed on Jun. 18, 2013, which claims priority and benefit to Japanese patent application No. 2012-148263 filed on Jul. 2, 2012. The entire contents of the foregoing patent applications are herein incorporated by reference.

### FIELD OF THE INVENTION

The present invention relates to a semiconductor inspection system and a method for preventing condensation at an interface part.

### BACKGROUND OF THE INVENTION

In a semiconductor device manufacturing process, a semiconductor inspection system using a probe apparatus and a tester is used for electrically inspecting semiconductor devices formed on, e.g., a semiconductor wafer.

In the probe apparatus, there is used a probe card having a plurality of probes to be in contact with electrode pads on the semiconductor wafer. The probe card is installed at a card clamp mechanism of the probe apparatus. The semiconductor wafer is attracted and held on a wafer mounting table and the wafer mounting table is moved by a driving unit. Accordingly, the probes of the probe card are brought into contact with electrodes of measurement target semiconductor devices formed on the semiconductor wafer and electrical connection therebetween is obtained. Further, inspection signals are supplied from the tester to the measurement target semiconductor devices via the probes. By measuring signals from the measurement target semiconductor devices, the electrical inspection of the measurement target semiconductor devices is performed (see, e.g., Japanese Patent Application Publication No. 2010-80775).

In the semiconductor inspection system configured as described above, characteristics of the measurement target semiconductor devices are inspected in a low temperature environment by cooling the semiconductor wafer or in a high temperature environment by heating the semiconductor wafer. In that case, if a cooled portion or the like is made to contact with air, condensation occurs and this may adversely affect the electrical measurement. To that end, there is suggested a technique for preventing condensation by supplying dry gas into a frame of a probe apparatus (see, e.g., Japanese Patent Application Publication No. H11-238765).

In the semiconductor inspection system that performs cooling of the measurement target semiconductor wafer or the like, it is required to prevent condensation at an interface part that electrically connects the probe card fixed to the probe apparatus and the tester.

### SUMMARY OF THE INVENTION

In view of the above, the present invention provides a semiconductor inspection system capable of reliably preventing condensation at the interface part that makes electrical connection and a method for preventing condensation at the interface part.

In accordance with one aspect of the invention, there is provided a semiconductor inspection system including: a probe apparatus configured to bring a probe into contact with a target object whose temperature is controlled so that the probe is electrically connected with the target object; a tester configured to inspect the target object by supplying an inspection signal to the target object and detect an output signal outputted from the target object; an interface part which electrically connects the probe with the tester; a vacuum seal mechanism configured to seal the interface part in an airtight state; a gas exhaust unit configured to evacuate the interface part to a depressurized atmosphere; and a dry gas supply unit configured to supply a dry gas into the evacuated interface part while controlling a flow rate of the dry gas.

In accordance with another aspect of the invention, there is provided a method for preventing condensation at an interface part which is provided in a semiconductor inspection system for electrically inspecting a target object whose temperature is controlled and which is disposed between a first device board and a second device board and electrically connects the first device board with the second device board by using an electrical connection device, the method comprising: evacuating a space where the electrical connection device is provided, to a depressurized atmosphere in the space, introducing a dry gas into the space at a predetermined flow rate.

### EFFECT OF THE INVENTION

In accordance with the present invention, the condensation at the interface part that makes electrical connection can be reliably prevented.

### BRIEF DESCRIPTION OF THE DRAWINGS

FIG. 1 schematically shows a configuration of a semiconductor inspection system in accordance with an embodiment of the present invention.

FIG. 2 schematically shows a configuration of an interface part of a probe apparatus shown in FIG. 1.

### DETAILED DESCRIPTION OF THE EMBODIMENTS

Hereinafter, embodiments of the present invention will be described with reference to the accompanying drawings.

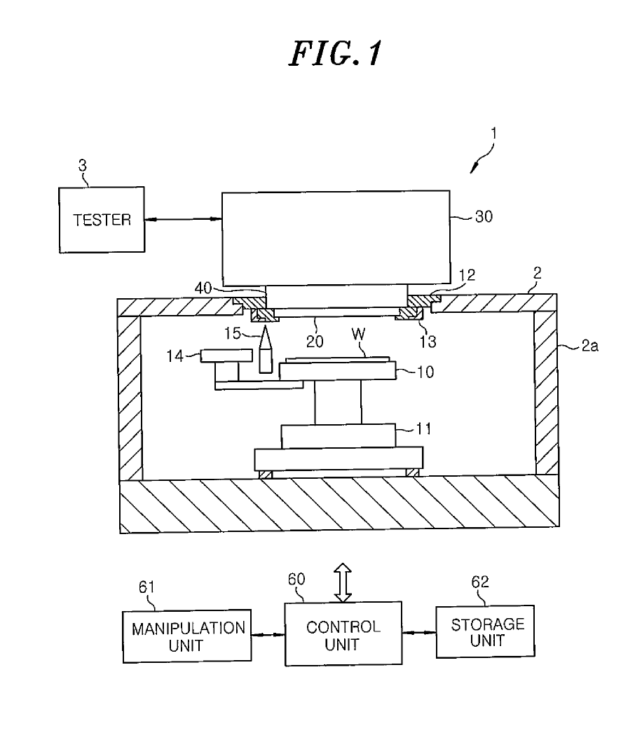

FIG. 1 schematically shows a configuration of an embodiment in which the present invention is applied to a semiconductor inspection system 1 for inspecting semiconductor devices formed on a semiconductor wafer. As shown in FIG. 1, the semiconductor inspection system 1 includes a probe apparatus 2 and a tester 3.

The probe apparatus 2 has a housing 2a. A wafer mounting table 10 for attractively holding and mounting thereon a semiconductor wafer W is provided within the housing 2a. The wafer mounting table 10 has a driving unit 11 and is movable in x, y, z, and 9 direction. Further, the wafer mounting table 10 has a temperature control unit, so that the semiconductor wafer W attracted and held on the wafer mounting table 10 can be cooled to a predetermined temperature, e.g., about −30° C.

The housing 2a has a circular opening is provided at a position above the wafer mounting table 10. An insert ring

12 is disposed along a peripheral portion of the circular opening. The insert ring 12 is provided with a card clamp mechanism 13. A probe card 20 is detachably held by the card clamp mechanism 13.

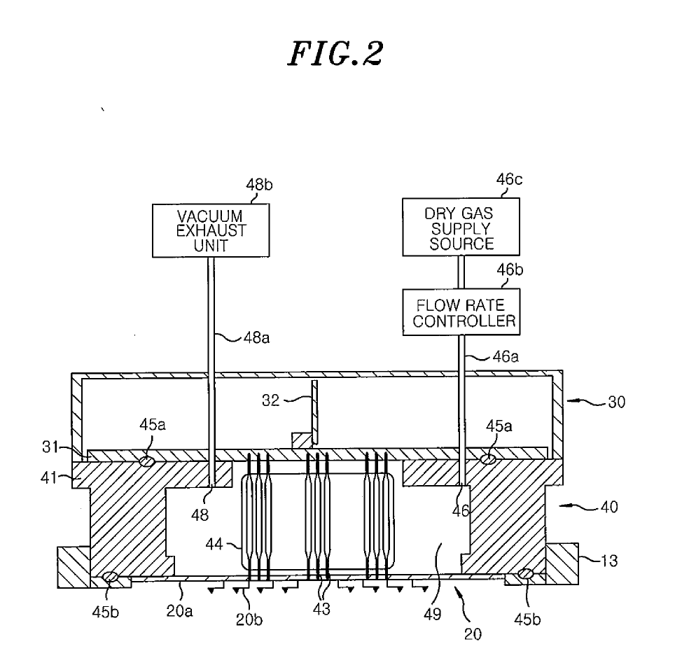

As shown in FIG. 2, the probe card 20 includes a circuit board 20a, a plurality of probes 20b electrically connected to the circuit board 20a, and the like. The probes 20b of the probe card 20 are arranged so as to correspond to the electrodes of the semiconductor devices formed on the semiconductor wafer W.

As shown in FIG. 1, provided at a side of the wafer mounting table 10 are a needle grinding plate 14 for grinding leading end portions of the probes and a camera 15 disposed to face upward to capture an image of an upper portion. The camera 15 is, e.g., a CCD camera or the like, and captures images of the probes of the probe card 20 and the like to perform position alignment between the probes and the electrodes.

A test head 30 connected to the tester 3 is provided above the probe card 20. Further, an interface part 40 is provided between the probe card 20 and the test head 30. The probe card 20 and the test head 30 are electrically connected via the interface part 40. A configuration of the interface part 40 will be described in detail later.

The tester 3 inspects the state of the semiconductor devices by transmitting inspection signals to the semiconductor devices formed on the semiconductor wafer W and detecting signals output from the semiconductor devices in accordance with the inspection signals. The tester 3 and the semiconductor devices formed on the semiconductor wafer W are electrically connected via the probe card 20, the interface part 40, and the test head 30.

The semiconductor inspection system 1 includes a control unit 60 having a CPU and the like. The entire operation of the semiconductor inspection system 1 is controlled by the control unit 60. Further, the control unit 60 has a manipulation unit 61 and a storage unit 62.

The manipulation unit 61 has a keyboard through which an operation manager inputs commands to manage the semiconductor inspection system 1, a display for visualizing and displaying an operational state of the semiconductor inspection system 1, and the like.

The storage unit 62 stores therein recipes such as control programs (software) to be used in realizing various processes performed in the semiconductor inspection system 1 under the control of the control unit 60, inspection condition data and the like. If necessary, a desired recipe is read out from the storage unit 62 under an instruction from the manipulation unit 61 and is executed by the control unit 60. Accordingly, various processes are performed in the semiconductor inspection system 1 under the control of the control unit 60. The recipes such as the control programs, the processing condition data and the like may be stored in a computer-readable computer storage medium (e.g., a hard disk, a CD, a flexible disk, a semiconductor memory or the like) or may be suitably transmitted from other devices via, e.g., a dedicated transmission line.

Hereinafter, a specific configuration of the interface part 40 will be described with reference to FIG. 2. As shown in FIG. 2, the interface part 40 is interposed between the probe card (first device board) 20 held by the card clamp mechanism 13 of the probe apparatus 2 and a mother board (second device board) 31 of the test head 30. The interface part 40 includes a base frame 41 disposed to make contact with the mother board 31. A module board 32 is provided at the mother board 31.

Provided within the base frame 41 is a pogo block 44 having a plurality of pogo pins (spring pins) 43 serving as electrical connection devices. Further, the probe card 20 and the mother board 31 are electrically connected by the pogo pins 43. Although a few pogo pins 43 are schematically illustrated in FIG. 2, there are actually provided, e.g., several thousands of pogo pins 43.

A vacuum seal mechanism 45a, e.g., an O-ring or the like, is provided between the mother board 31 and the base frame 41 to airtightly seal a gap between the mother board 31 and the base frame 41. In addition, a vacuum seal mechanism 45b, e.g., an O-ring or the like, is provided between the base frame 41 and the probe card 20 to airtightly seal a gap between the base frame 41 and the probe card 20.

In the interface part 40, the vacuum seal mechanisms 45a and 45b such as O-rings or the like are provided between the vertically stacked members, i.e., the mother board 31, the base frame 41, and the probe card 20, as described above. Accordingly, a space 49 surrounded by the mother board 31, the base frame 41 and the probe card 20 is airtightly sealed.

A dry gas inlet path 46 is provided at the base frame 41. The dry gas inlet path 46 is connected to one end of the dry gas inlet line 46a. Further, a flow rate controller 46b is provided in the dry gas inlet line 46a. The other end of the dry gas inlet line 46a is connected to a dry gas supply source 46c.

Further, a vacuum exhaust path 48 is provided at the base frame 41. The vacuum exhaust line 48 is connected to one end of a vacuum exhaust line 48a. The other end of the vacuum exhaust line 48a is connected to a vacuum exhaust unit 48b including a vacuum pump and the like.

Moreover, the space 49 surrounded by the mother board 31, the base frame 41, and the probe card 20 is evacuated by the vacuum exhaust unit 48b through the vacuum exhaust line 48a and the vacuum exhaust path 48 to a predetermined depressurized atmosphere, e.g., a depressurized atmosphere lower than the atmospheric pressure by about 10 kPa to 100 kPa (about 35 kPa to 55 kPa in the present embodiment). Accordingly, contact pressures of the pogo pins 43 to the mother board 31 and the probe card 20 can be ensured and condensation in the space 49 can be prevented to a certain extent.

In the present embodiment, the space 49 is set to a depressurized atmosphere as described above and a predetermined dry gas, e.g., dry air, is supplied from the dry gas supply source 46c into the space 49 via the flow rate controller 46b, the dry gas inlet line 46a and the dry gas inlet path 46. The dry gas is supplied at a flow rate controlled by the flow rate controller 46b, e.g., 0.1 l/min to 3 l/min and preferably 0.1 l/min to 1 l/min.

As described above, in the present embodiment, the space 49 is maintained at a predetermined depressurized atmosphere while the dry gas is introduced into the space 49 at a controlled flow rate. Accordingly, an atmosphere dew point in the space 49 is lowered and the depressurized atmosphere can be maintained. As a result, the condensation can be prevented.

For example, if the dry gas is not introduced during the depressurization of the space 49, the atmosphere dew point is not sufficiently lowered and condensation may occur in the space 49. The possibility of occurrence of condensation is especially increased when air enters from the outside into the space 49. In accordance with the present embodiment, the atmosphere dew point in the space 49 can be lowered without being affected by the ambient atmosphere as described above. As a result, the occurrence of condensation in the space 49 can be reliably prevented.

When the semiconductor devices formed on the semiconductor wafer W are electrically inspected by the semiconductor inspection system 1 configured as described above, the semiconductor wafer W is mounted and attractively held on the wafer mounting table 10 of the probe apparatus 2. At this time, the wafer mounting table 10 is cooled to a desired inspection temperature, e.g., a low temperature of about −30° C., at which the semiconductor wafer W is inspected.

In the interface part 40, the space 49 is evacuated to a predetermined depressurized atmosphere, e.g., a depressurized atmosphere lower than the atmospheric pressure by about 10 kPa to 100 kPa (about 35 kPa to 55 kPa in the present embodiment), and dry gas, e.g., dry air, is supplied into the space 49 at a predetermined flow rate controlled to, e.g., about 0.1 l/min to 3 l/min, and preferably about 0.1 l/min to 1 l/min. By maintaining this state, the condensation at the interface part 40 can be reliably prevented.

Further, the electrical connection is made by bringing the electrodes of the semiconductor wafer W into contact with the probes 20b of the probe card 20 by moving the semiconductor wafer W together with the wafer mounting table 10 by the driving unit 11. Accordingly, the reliability of the electrical characteristics of the semiconductor devices is inspected by the tester 3 connected to the test head 30.

While the embodiments of the present invention have been described, the present invention may be variously modified without being limited to the above embodiments. For example, in the above embodiments, the pogo pins 43 are provided, as electrical connection devices in the interface part 40. However, an electrical connection device other than the pogo pins 43 may be used.

This application claims priority to Japanese Patent Application No. 2012-148263 filed on Jul. 2, 2012, the entire contents of which are incorporated herein by reference.

### DESCRIPTION OF REFERENCE NUMERALS

1: semiconductor inspection system
2: probe apparatus
2a: housing
3: tester
10: wafer mounting table
11: driving unit
12: insert ring
13: card clamp mechanism
14: needle grinding plate
15: camera
20: probe card
20a: circuit board
20b: probe
30: test head
31: mother board
40: interface part
41: base frame
43: pogo pin
44: pogo block
45a, 45b: vacuum seal mechanism
46: dry gas inlet path
46a: dry gas inlet line
46b: flow rate controller
46c: dry gas supply source
48: vacuum exhaust path
48a: vacuum exhaust line
48b: vacuum exhaust unit
49: space
60: control unit
61: manipulation unit
62: storage unit

1. A semiconductor inspection system comprising:
a probe apparatus configured to bring a probe into contact with a target object whose temperature is controlled to a predetermined temperature so that the probe is electrically connected with the target object;
a tester configured to inspect the target object by supplying an inspection signal to the target object and detect an output signal outputted from the target object;
an interface part which electrically connects the probe with the tester;
a vacuum seal mechanism configured to seal the interface part in an airtight state;
a gas exhaust unit configured to evacuate the interface part to a depressurized atmosphere; and
a dry gas supply unit configured to supply a dry gas into the evacuated interface part while controlling a flow rate of the dry gas.

2. The semiconductor inspection system of claim 1, wherein the dry gas supply unit supplies the dry gas at the flow rate ranging from 0.1 l/min to 3 l/min.

3. The semiconductor inspection system of claim 1, wherein the tester includes a tester head having a mother board therein, and wherein the interface part is provided in between the mother board of the test head of the tester and a probe card fixed to the probe apparatus.

4. The semiconductor inspection system of claim 3, wherein the interface part includes therein a plurality of pogo pins for electrically connecting the probe card with the mother board.

5. The semiconductor inspection system of claim 1, wherein the probe apparatus includes: a mounting table configured to mount thereon the measurement target object; and a driving mechanism configured to move the mounting table to bring the target object into contact with the probe.

6. A method performed in a semiconductor inspection system including a first device board, a second device board and an interface part having an electrical connection device which electrically connects the first device board with the second device board, for preventing condensation at the interface part, the method comprising:
evacuating a space where the electrical connection device is provided, to a depressurized atmosphere in the space, and
introducing a dry gas into the space at a predetermined flow rate.

7. The method of claim 6, wherein the first device board includes a probe card and the second device board includes a mother board of a test head of a tester.
